(19) United States
(12) Patent Application Publication
(10) Pub. No.: US 2006/0252163 A1
(43) Pub. Date: Nov. 9, 2006

(54) Peelable photoresist for carbon nanotube cathode

(75) Inventors: Zvi Yaniv, Austin, TX (US); Mohshi Yang, Austin, TX (US); Dongsheng Mao, Austin, TX (US)

Correspondence Address: Kelly K. Kordzik;Winstead Sechrest & Minick P.C., P.O. Box 50784, Dallas, TX, 75201, US

(73) Assignee: Nano-Proprietary, Inc., Austin, TX (US)

(21) Appl. No.: 11/341,300

(22) Filed: Jan. 27, 2006

Related U.S. Application Data
(63) Continuation-in-part of application No. 11/124,332, filed on May 6, 2005.
(63) Continuation-in-part of application No. 10/269,577, filed on Oct. 11, 2002, now abandoned.
(60) Provisional application No. 60/343,642, filed on Oct. 19, 2001.
(60) Provisional application No. 60/348,856, filed on Jan. 15, 2002.
(60) Provisional application No. 60/369,794, filed on Apr. 4, 2002.

(51) Int. Cl. H01L 21/00

(52) U.S. Cl. 438/20

(57) ABSTRACT

A method for forming a field emission cathode device is disclosed using a peelable photoresist with standard photolithography processes for patterning a deposition mask, except that the peelable photoresist can be peeled away in dry form. The method offers standard photoresist accuracy with the advantage of high patterning resolution for producing carbon nanotube (CNT) field emitter displays. Example methods using a single peelable photoresist layer, and using two distinct layers of photoresist and peelable film, are presented. Since the method does not require wet processes after CNT deposition, it ensures enhanced CNT emitter performance. In addition, an activation process that liberates CNTs can be performed just before a tape lamination and peeling process step. In this manner, all superfluous nanoparticle material remains confined between the tape and photoresist films, which are removed together and properly discarded.

The present application is a continuation-in-part of U.S. patent application Ser. No. 11/124,332, and is also a continuation-in-part of U.S. patent application Ser. No. 10/269,577, which claims priority to provisional patent applications: 60/343,642; 60/348,856; and 60/369,794.

### TECHNICAL FIELD

The present invention relates in general to photolithography, and in particular to applying a peelable photoresist to manufacture carbon nanotube (CNT) cathodes.

### BACKGROUND INFORMATION

Carbon nanotube (CNT) cathode structures are highly effective field emitters for generating cathode rays, exhibiting a high emission current at a low threshold voltage. CNT cathodes can be fabricated, using procedures known for manufacturing semiconductors, as a plurality of microcells to generate an array of pixels, which form the basis for a display device, such as a television, or a computer monitor. Fabrication of CNT cathodes into an array of pixels typically requires masks to align the pixels and deposit CNTs in the form of CNT ink onto the pixels.

There are two well-known methods in the art to deposit the CNT ink, either using a shadow mask to spray or print CNT ink to define pixel areas, or using a standard photolithography process (spin coating; baking; exposing; developing; wet etching; and wet stripping) to define pixels. Each of these two methods has a unique drawback associated with it.

Using the shadow mask method, the alignment tolerance of the pixels is limited by the mechanical accuracy of positioning the shadow mask. This mask alignment limitation constrains the pixel resolution. Also, there is a gap between the substrate and the shadow mask that causes CNT ink or solution to leak through the mask edge. Referring to FIG. 1, as a result, CNT ink 105 can be deposited on the sidewall of the pixel well 110 or between the mask 102 and the device. This contamination by conductive CNT ink 105 in undesirable areas of the device increases the likelihood of short circuits when the contact grid structure for the pixels is subsequently applied during manufacture of the display. The shadow mask method is therefore not suitable for industrial applications involving high volume manufacturing subject to rigorous quality standards.

Using a standard photolithography process, involving a photoresist coating and wet stripping of the resist, CNT material becomes exposed to a chemical solution and water, which adversely affects the CNT emitter performance. The degradation of the sensitive CNT material caused by wet stripping and wet rinsing results in higher threshold voltages and lower emission currents of the CNT cathode. Therefore, there is a need in the art for a photolithography method which does not rely on wet processes to remove the photoresist mask.

### SUMMARY OF THE INVENTION

The present invention addresses the foregoing need by providing a method of using a peelable photoresist that can be patterned using photolithography for producing a field emission cathode device. The cathode device is patterned for making matrix-addressable display pixels using carbon nanotube (CNT) ink. The photoresist film can be peeled off after the CNT ink layer is deposited, without exposure of the CNT material to solvents and wet resist stripping steps that normally destroy CNT emission performance as a result of standard photolithography processes.

The merits of the present invention over the prior art for defining pixel area are manifold. A peelable photoresist provides the more accurate alignment and higher pixel resolution of photolithography as opposed to using shadow masks. A peelable photoresist eliminates the need for a shadow mask and thus eliminates any associated contamination effects of CNT ink becoming deposited in undesirable areas of the device, as can occur using shadow masks. A peelable photoresist eliminates the need for wet processes during photolithography mask removal, and thus preserves high CNT emitter performance of the pixel cathode. Additionally, a peelable photoresist may be used to avoid wet stripping in other applications, such as manufacturing of integrated circuits, where standard photolithography processes are used.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates deposition of CNT ink using the shadow mask method of the prior art;

FIGS. 2A and 2B illustrate the initial two steps of one embodiment of the present invention that implements a single peelable resist layer: coating, exposing, developing the peelable photoresist; and depositing the CNT ink layer;

FIGS. 2C and 2D illustrate third and fourth steps of one embodiment of the present invention that implements a single peelable resist layer: activating the CNT ink with nanoparticles; and laminating the tape on top of the existing structure;

FIGS. 2E and 2F illustrate fifth and final steps of one embodiment of the present invention that implements a single peelable resist layer: peeling the tape to remove unwanted CNT ink with the photoresist; and the final resulting structure of the CNT ink emitter cathodes;

FIGS. 3A and 3B illustrate the first two steps of one embodiment of the present invention that implements peelable resist comprising a peelable layer and a standard photoresist layer: applying the peelable film; and applying the photoresist;

FIGS. 3C and 3D illustrate third and fourth steps of one embodiment of the present invention that implements peelable resist comprising a peelable layer and a standard photoresist layer: exposing with UV light; and developing the photoresist;

FIGS. 3E and 3F illustrate fifth and sixth steps of one embodiment of the present invention that implements peelable resist comprising a peelable layer and a standard photoresist layer: stripping the photoresist; and depositing the CNT ink layer;

FIGS. 3G and 3H illustrate seventh and eighth steps of one embodiment of the present invention that implements peelable resist comprising a peelable layer and a standard photoresist layer: activating the CNT ink with nanoparticles; and laminating the tape on top of the existing structure;

FIGS. 3F and 3K illustrate ninth and final steps of one embodiment of the present invention that implements peelable resist comprising a peelable layer and a standard photoresist layer: peeling the tape to remove unwanted CNT ink with the peelable film; and the final resulting structure of the CNT ink emitter cathodes;

FIG. 4 illustrates a data processing system; and

FIG. 5 illustrates a portion of a field emission display made using a cathode in a triode configuration.

### DETAILED DESCRIPTION

In the following description, numerous specific details are set forth such as specific substrate materials to provide a thorough understanding of the present invention. However, it will be obvious to those skilled in the art that the present invention may be practiced without such specific details. In other instances, well-known circuits have been shown in block diagram form in order not to obscure the present invention in unnecessary detail. For the most part, details concerning timing considerations and the like have been omitted inasmuch as such details are not necessary to obtain a complete understanding of the present invention and are within the skills of persons of ordinary skill in the relevant art.

Refer now to the drawings wherein depicted elements are not necessarily shown to scale and wherein like or similar elements are designated by the same reference numeral through the several views.

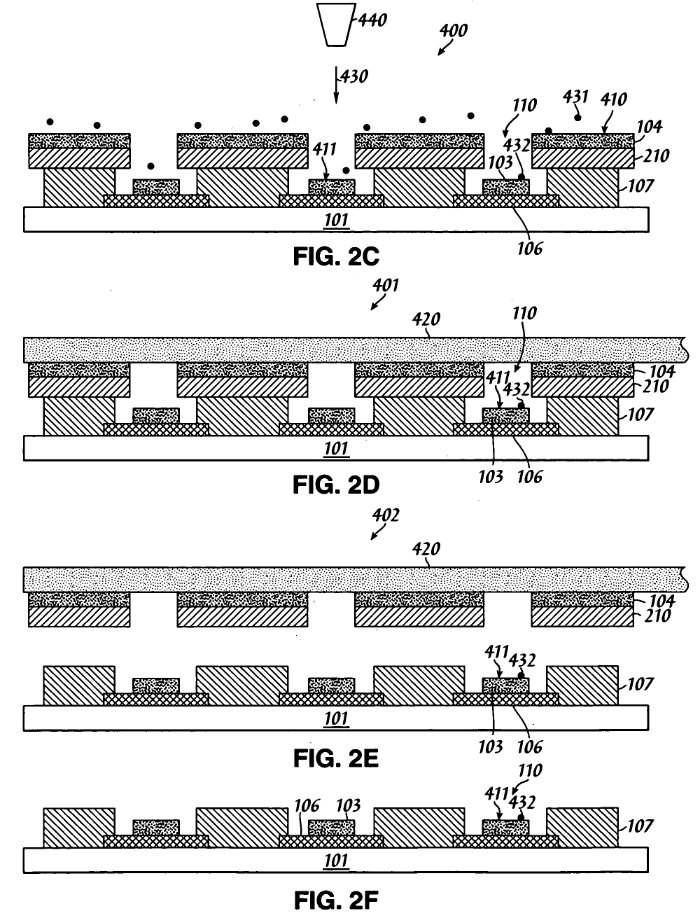

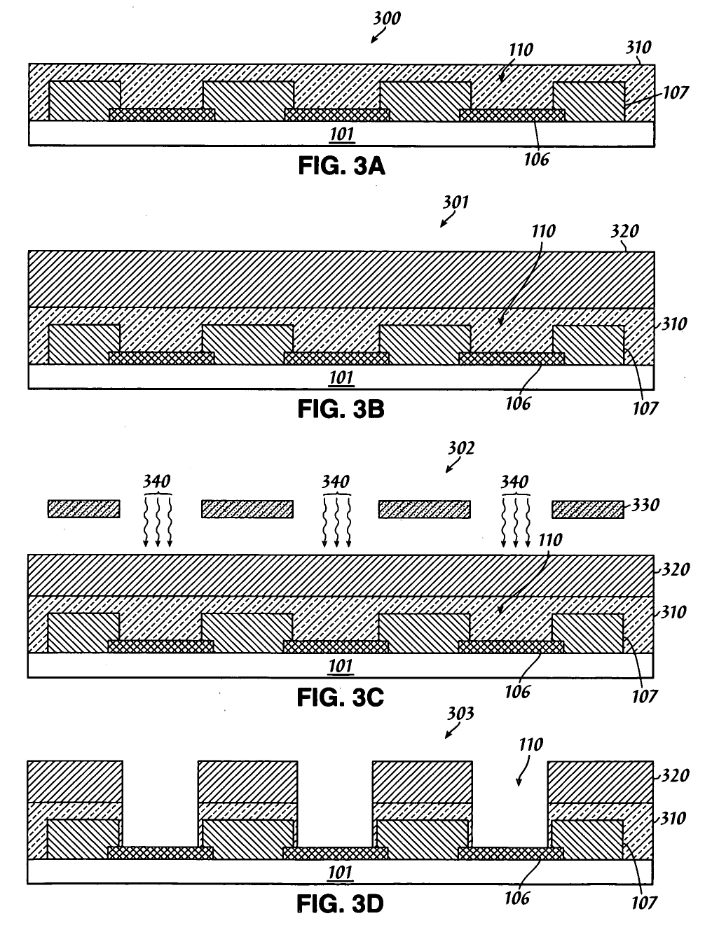

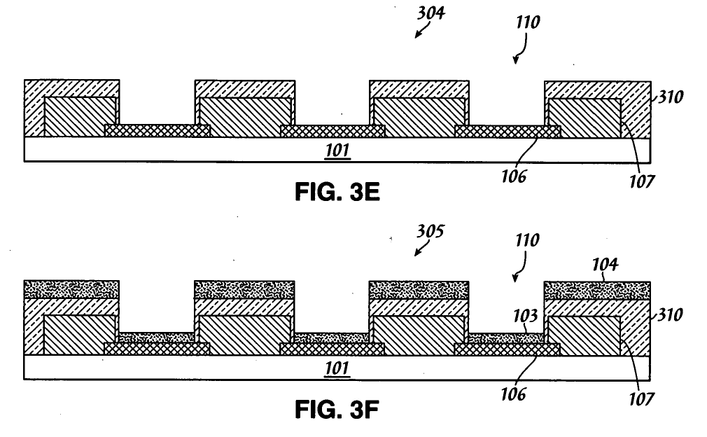

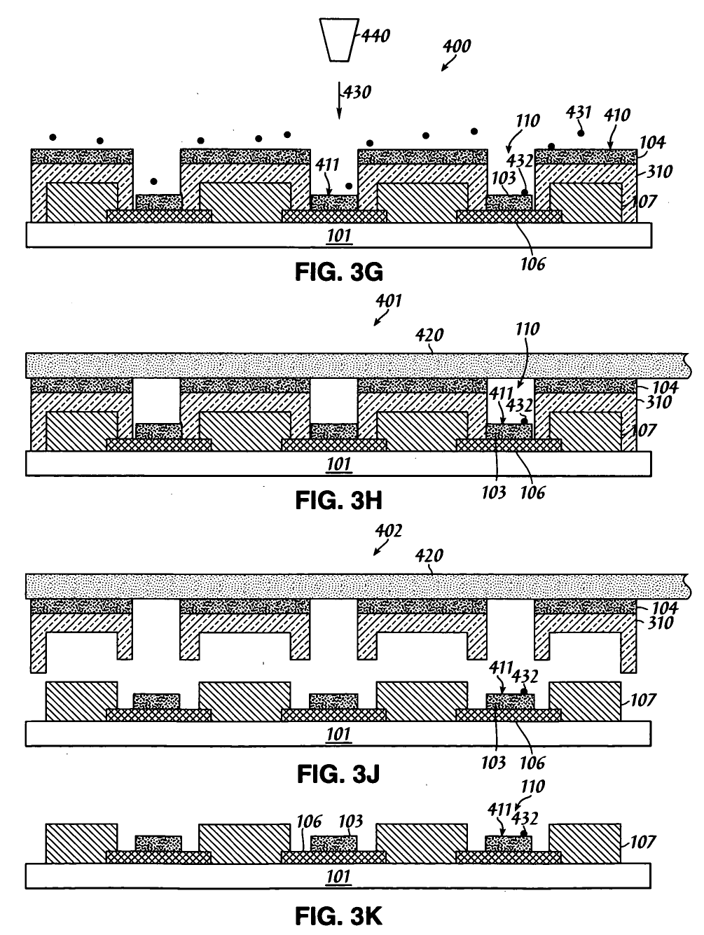

The present invention provides a method of using a peelable photoresist that can be patterned using photolithography for producing field emission display pixels using CNT ink as the cathode material. The steps of the procedure in one embodiment of the current invention to process a cathode by using peelable photoresist comprising a single photoresist layer are illustrated in FIGS. 2A through 2F. The steps of the procedure in another embodiment of the current invention to process a cathode by using peelable photoresist comprising a first peelable layer and a second photoactive layer are illustrated in FIGS. 3A through 3K. Certain nonessential method steps may be omitted or repeated as required in other embodiments.

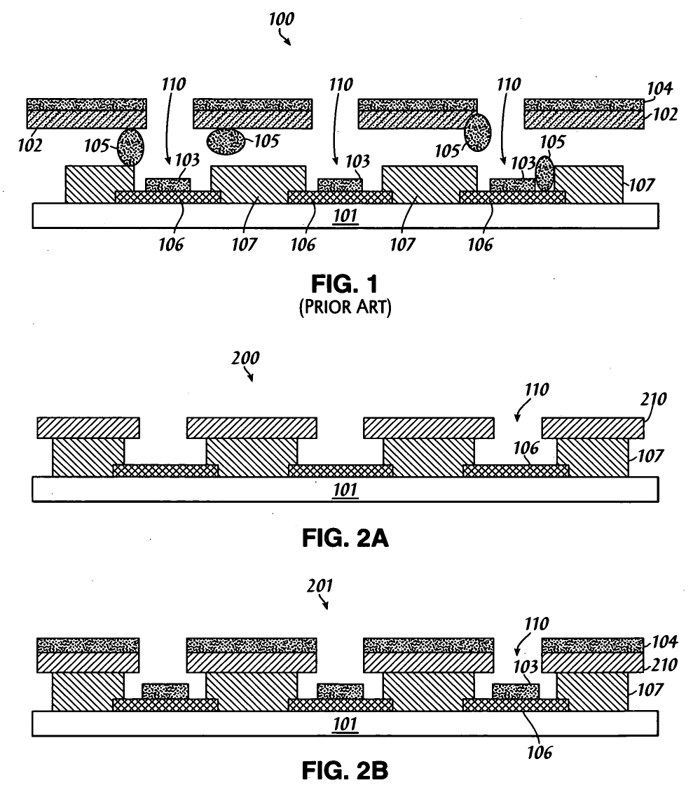

FIG. 1 illustrates the result of the prior art method 100 of spraying or printing CNT ink 103, 104, 105 using a shadow mask 102 to expose only the unmasked portions of the composite structure below the mask 102 for coating with CNT ink. On the substrate 101, the trace feed line and pixel electrode pad layer 106 is deposited using a conducting paste. Then, the insulator film layer 107 is deposited to isolate between individual pixel cells 110. A shadow mask 102 is mechanically positioned a distance above the composite structure 101, 106, 107. Then, CNT ink 103, 104, 105 is sprayed or printed over the shadow mask 102. The problems with the deposition of CNT ink 103, 104, 105 are illustrated in FIG. 1. Ideally, the CNT ink 104, 103 is only deposited on the masked 102 and unmasked (on the pixel electrode pads 106) portions of the composite structure 101, 106, 107. However, it is observed that, due to the distance between the shadow mask 102 and the composite structure 101, 106, 107, some CNT ink 105 becomes deposited in inappropriate locations. The contamination effects of the excessive CNT ink 105, which leaks through the mask edge onto the sidewall of the pixel well 110 or onto the insulating film layer 107, may include a short circuit in the grid structure for addressing the individual pixels. Also, the mechanical positioning of the shadow mask constrains the pixel resolution that may be attained using this method. For the above-stated reasons, the shadow mask method 100 is rendered unsuitable for industrial scale, high volume manufacturing, where rigorous quality standards are required. In the present invention, a method which overcomes these problems using a peelable photoresist has been developed.

FIGS. 2A and 2B illustrate one example method, wherein a single layer peelable photoresist 210 is applied 200. Referring to FIG. 2A, on the substrate 101, the trace feed lines and pixel electrode pad layer 106 is screen printed using a silver conducting paste (DuPont #7713), followed by baking and firing. Then, the insulator film layer 107 is deposited to isolate between individual pixel cells 110 by screen printing an insulating film 107 (DuPont #9370), followed by baking and firing. Next, a peelable photoresist 210 (Transfer Devices xFILM-R) is spin or spray coated on the composite structure 101, 106, 107. This is followed by baking, exposing the mask pattern, and developing the photoresist 210. The result of this process 200 is illustrated in FIG. 2A. The unmasked portions of the photoresist 210 reveal the centers of the pixel electrode pads 106. In the next process step 201, illustrated in FIG. 2B, a CNT ink is sprayed or printed, resulting in a layer of CNT ink 104 deposited on the photoresist 210, and a layer of CNT ink 103 deposited on the pixel electrode pads 106 to form the cathode structure. Note that since there is no gap between the photoresist 210 and the CNT ink 104, no undesired CNT ink 105 is deposited as shown in FIG. 1. The next processing step 400 can be the one illustrated by FIG. 2C, which activates the CNT material 103 by implanting additional nanoparticles 431 (in the current example, CNTs) into the surface 410, 411 of the previously deposited CNT ink layer 103, 104. In one example method, the implantation 400 is performed using a micromachining bead-blaster which bombards the surface 410, 411 with nanoparticles 431 using a positionable nozzle 440 from a direction 430 normal to the surface. In the bead-blasting method 400, different implantation scenarios, including various orientations, carrier bead-CNT mixtures, and positioning regimes, may be practiced with the present invention. In this manner, the surface of the CNT emitter 411 is activated due to a higher concentration of nanoparticles 432 embedded into the cathode surface 411, which enhances cathode performance. Other activation mechanisms may also be possible within the scope of the present invention. Note that a layer 210 in FIG. 2C represents the single layer peelable photoresist. As the next process step, FIG. 2D, illustrates, the lamination 401 of an adhesive tape 420 (3M), comprising a tape layer on one side and an adhesive layer on the other side, is performed on top of the CNT ink 104 deposited on the masked pattern of peelable photoresist 210. The lamination 401 may be augmented with additional heat or pressure, or a combination thereof, as required in other embodiments. After lamination 401, the adhesive tape is firmly bonded to the CNT ink layer 104, which is, in turn, firmly bonded to the masked pattern of peelable photoresist 210. The last processing step for a single layer photoresist method of the current invention is illustrated in FIG. 2E; this step involves peeling the tape from the composite structure below, thereby removing the bonded CNT ink layer 104 along with the peelable photoresist 210. Note that since the extraneous CNT ink layer 104 is neatly packaged between the adhesive tape 420 and the peelable photoresist 210, the risk of contaminating the plurality of now finished cathode structures (pixel wells) 110 with CNT ink 104 has been effectively eliminated. FIG. 2F illustrates the final product of a single layer photoresist process, a CNT emitter with a plurality of cathode structures, which can be further processed to create a display with addressable pixels.

FIGS. 3A-3K illustrate another example method, wherein a peelable resist comprising two layers, a first layer of peelable material 310 and a second layer of photosensitive material 320, is applied 300, 301. Referring to FIG. 3A, on the substrate 101, the trace feed lines and pixel electrode pad layer 106 is screen printed using a silver conducting paste (DuPont #7713), followed by baking and firing. Then, the insulator film layer 107 is deposited to isolate between individual pixel cells 110 by screen printing an insulating film 107 (DuPont #9370), followed by baking and firing. Next, a peelable film layer 310 (Transfer Devices xFILM) is spin or spray coated on the composite structure 101, 106, 107, as shown in FIG. 3A; immediately thereafter follows spin or spray coating a standard photoresist 320 as shown in FIG. 3B. Next the composite structure in FIG. 3B is baked. Then, as shown in FIG. 3C, the mask pattern is exposed 302 using UV light 340 and a standard photolithography mask 330. Next, as shown in FIG. 3D, the peelable resist layers 310, 320 are developed and stripped 303. Note that this process 303 may utilize standard chemical solutions or wet stripping without degrading the CNT emitter performance, since no CNT ink 103 is present yet. This process 303 exposes the unmasked portions (pixel cells) 110 of the photomask 330, which reveals the centers of the pixel electrode pads 106. Thereafter, as shown in FIG. 3E, the photoresist layer 320 is stripped 304. Note that this process 304 may utilize standard chemical solutions or wet stripping without degrading the CNT emitter performance, since no CNT ink 103 is present yet. In the subsequent process step 305, illustrated in FIG. 3F, a CNT ink is sprayed or printed on the substrate, resulting in a layer of CNT ink 104 deposited on the peelable material 310, and a layer of CNT ink 103 deposited on the pixel electrode pads 106 to form the cathode structure. Note that since there is no gap between the peelable material 310 and the CNT ink 104, no undesired CNT ink 105 is deposited as shown in FIG. 1. The next processing step 400 can be the one illustrated by FIG. 3G, which activates the CNT material 103 by implanting additional nanoparticles 431 (in the current example, CNTs) into the surface 410, 411 of the previously deposited CNT ink layer 103, 104. In one example method, the implantation 400 is performed using a micromachining bead-blaster which bombards the surface 410, 411 with nanoparticles 431 using a positionable nozzle 440 from a direction 430 normal to the surface. In the bead-blasting method 400, different implantation scenarios, including various orientations, carrier bead-CNT mixtures, and positioning regimes, may be practiced with the present invention. In this manner, the surface of the CNT emitter 411 is activated due to a higher concentration of nanoparticles 432 embedded into the cathode surface 411, which enhances cathode performance. Other activation mechanisms may also be possible within the scope of the present invention. Note that a layer 310 in FIG. 3G represents the peelable film 310. As the next process step, FIG. 3H, illustrates, the lamination 401 of an adhesive tape 420 (3M), comprising a tape layer on one side and an adhesive layer on the other side, is performed on top of the CNT ink 104 deposited on the masked pattern of peelable film 310. The lamination 401 may be augmented with additional heat or pressure, or a combination thereof, as required in other embodiments. After lamination 401, the adhesive tape is firmly bonded to the CNT ink layer 104, which is, in turn, firmly bonded to the masked pattern of peelable film 310. The last processing step in the present example method is illustrated in FIG. 3J; this step involves peeling the tape from the composite structure below, thereby removing the bonded CNT ink layer 104 along with the peelable film 310. Note that since the extraneous CNT ink layer 104 is neatly packaged between the adhesive tape 420 and the peelable film 310, the risk of contaminating the plurality of now finished cathode structures (pixel wells) 110 with CNT ink 104 has been effectively eliminated. FIG. 3K illustrates the final product of the process, a CNT emitter with a plurality of cathode structures, which can be further processed to create a display with addressable pixels.

Note that the structures in FIG. 2F and FIG. 3K are identical. Both aforementioned example processes, either using a single layer of peelable photoresist 210, or using a peelable resist comprising two layers, a first layer of peelable material 310 and a second layer of photosensitive material 320, may thus be practiced to yield the same final CNT emitter product.

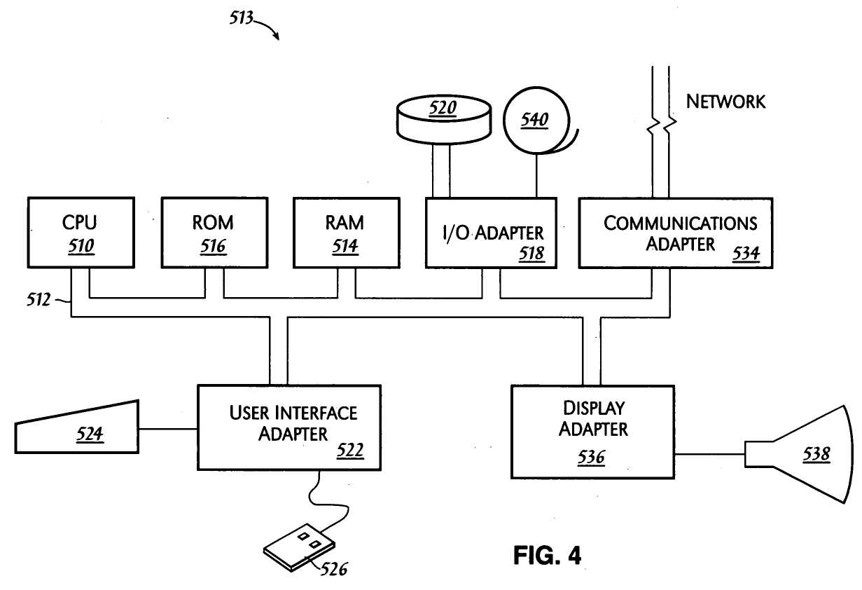

A representative hardware environment for practicing the present invention is depicted in FIG. 4, which illustrates an exemplary hardware configuration of data processing system 513 in accordance with the subject invention having central processing unit (CPU) 510, such as a conventional microprocessor, and a number of other units interconnected via system bus 512. Data processing system 513 includes random access memory (RAM) 514, read only memory (ROM) 516, and input/output (I/O) adapter 518 for connecting peripheral devices such as disk units 520 and tape drives 540 to bus 512, user interface adapter 522 for connecting keyboard 524, mouse 526, and/or other user interface devices such as a touch screen device (not shown) to bus 512, communication adapter 534 for connecting data processing system 513 to a data processing network, and display adapter 536 for connecting bus 512 to display device 538. CPU 510 may include other circuitry not shown herein, which will include circuitry commonly found within a microprocessor, e.g., execution unit, bus interface unit, arithmetic logic unit, etc. Display device 538 represents possible embodiments of the present invention.

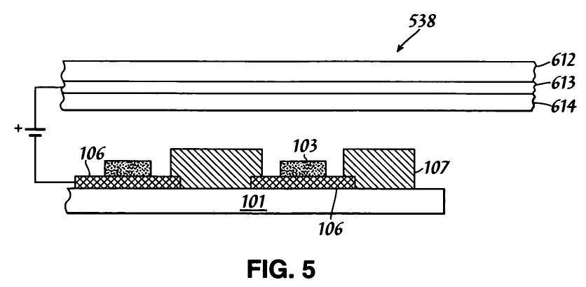

FIG. 5 illustrates a portion of a field emission display 538 made using a cathode in a diode configuration, such as created above. Included with the cathode is a conductive layer 106 and the CNT emitter 103. The anode may be comprised of a glass substrate 612, and indium tin layer 613, and a cathodoluminescent layer 614. An electrical field is set up between the anode and the cathode. Such a display 538 could be utilized within a data processing system 513, such as illustrated with respect to FIG. 4.

Although the present invention and its advantages have been described in detail, it should be understood that various changes, substitutions and alterations can be made herein without departing from the spirit and scope of the invention as defined by the appended claims.

What is claimed is:

1. A method for forming a field emission cathode device, comprising a plurality of cathode structures, comprising the steps of:
forming a conducting film comprising a plurality of feed lines and electrode pads on a substrate using a conducting material;
forming an insulating film comprising a plurality of barrier ribs and insulating pads on said substrate and said conducting film using an insulating material;
coating said substrate, said conducting film, and said insulating film with a layer of peelable photoresist; and
exposing and developing said peelable photoresist using standard photolithography processes to generate a mask pattern in said peelable photoresist which unmasks a plurality of electrode pads.

2. The method as recited in claim 1, further comprising the step of:
coating a composite structure of said substrate, said conducting film, said insulating film, and said mask pattern in said peelable photoresist with a layer of nanoparticle ink, such that a layer of nanoparticle ink is deposited on the masked portions and the plurality of unmasked portions of said peelable photoresist.

3. The method of claim 2, wherein said nanoparticle ink contains carbon nanotubes (CNTs).

4. The method as recited in claim 2, further comprising the step of:
activating said layer of nanoparticle ink for field emission of cathode rays by implanting nanoparticles onto a surface of said layer of nanoparticle ink, particularly activating thereby said plurality of unmasked portions of said peelable photoresist coated with said nanoparticle ink.

5. The method as recited in claim 2, further comprising the step of:
laminating with an adhesive tape the composite structure of said substrate, said conducting film, said insulating film, said mask pattern in said peelable layer, and the layer of nanoparticle ink in contact with said peelable layer, such that only the nanoparticle ink layer deposited on the masked portions of said peelable layer is contacted with said adhesive tape;

6. The method as recited in claim 5, further comprising the step of:
detaching said adhesive tape from said composite structure, such that said adhesive tape, the nanoparticle ink in contact with said adhesive tape and said peelable layer, and said peelable layer are removed together.

7. The method of claim 1, wherein said peelable photoresist comprises:
a first applied layer of peelable material; and
a second applied layer of photoresistive material, such that both first and second applied layers are completely and identically removed from the unmasked regions of said mask pattern generated upon said exposing and said developing using standard photolithography processes.
